(19) United States
(12) Patent Application Publication
(10) Pub. No.: US 2021/0229462 A1
(43) Pub. Date: Jul. 29, 2021

(54) SYSTEMS FOR AND METHOD OF LASER MARKING WITH REDUCED MAXIMUM OPERATIONAL OUTPUT POWER

(71) Applicant: DATALASE LIMITED, Widnes Cheshire (GB)

(72) Inventors: John V. Cridland, Widnes Cheshire (GB); Tristan Phillips, Widnes Cheshire (GB)

(73) Assignee: DATALASE LIMITED, Widnes Cheshire (GB)

(21) Appl. No.: 17/051,378

(22) PCT Filed: Apr. 24, 2019
(86) PCT No.: PCT/GB2019/051147

§ 371 Date: Oct. 28, 2020

(30) Foreign Application Priority Data
May 1, 2018 (GB) 1807161.3

(51) Int. Cl. B41J 2/455; B23K 26/06; B23K 26/40; B23K 26/064; B23K 26/364; B23K 26/08; B41J 2/45; B41M 5/26; G02B 6/42; H01S 5/40

(52) U.S. Cl. CPC B41J 2/455; B23K 26/0608; B23K 26/0613; B23K 26/0648; B23K 26/40; B23K 26/064; H01S 5/4025; B23K 26/08; B23K 26/0626; B41J 2/45; B41M 5/26; G02B 6/4249; B23K 26/364

(57) ABSTRACT

A system for laser marking a substrate includes a multi-emitter array (16) for directing radiation onto a substrate. The multi-emitter array has a radiation guide (19) defining a number of discrete emission channels (20) with emitting ends (20a) of the emission channels (20) arranged in an array. Each emission channel (20) is coupled at its opposing end with two or more laser diodes (18a, 18b). The laser diodes (18a, 18b) are operated at a maximum operational output power (Pₒₚ) sufficiently below their rated maximum power (Pₘ) to provide acceptable levels of reliability whilst providing a combined radiation (24) emitted from each channel (20) having a power high enough to achieve increased operational speeds. The multi-emitter array (19) may comprise a number of optical fibres (26) whose emitter ends are arranged in an array. The system is particularly suited for inkless printing on substrates susceptible to colour change when irradiated.

### TECHNICAL FIELD OF THE INVENTION

The present invention relates to laser marking. In particular, the present invention relates to systems and methods for laser marking which comprise a multi-emitter array.

### BACKGROUND TO THE INVENTION

It is known to use laser marking and imaging systems for non-contact, inkless recording of image information on a substrate, such as labels, that comprise a colour change material. Upon controlled exposure to laser radiation from the marking system, portions of the substrate change colour forming a desired image. The image may be monotone or coloured depending on the material and/or the nature of the exposure. The image may comprise text, numbers, codes or the like as well as pictographic elements. Such colour change technology is disclosed for example in WO2016135468 A1, WO2016097667 A1, WO2015015200 A1, and WO2010026408 A2.

Conventional laser marking and imaging systems that use a single laser and scan the beam over the required field using galvanometer tilting mirrors together with a focusing lens are well known in the coding and marking industry. They work well but in applications where the target substrate moves at high speed and there is a high density of information or high fill factor for the image they run into problems, principally because the galvanometer scan speed limits their performance through inertia, heat input and dissipation. To overcome this problem, it is known to use laser marking systems which incorporate a multi-emitter array into an imaging or printing head. In some instances, the multi-emitter array may simply comprise an array of adjacent laser diodes. More usually, the array may comprise the emitting ends of multiple optical fibres, with each optical fibre being coupled at its other end to a respective laser diode. Each optical fibre defines an emission channel through which radiation from the respective laser diode passes to irradiate the substrate as it moves in front of the head. The individual laser diodes are modulated based on the image requirements to generate an array of dots or pixels in the substrate. The benefit of this approach is that the imaging speed is independent of image content and multi-emitter array systems have been developed which are capable of recording image information on colour change substrates moving at speeds up to and above 2 m/s.

For use with a known colour change substrate technology, a fluence (or energy density) Ed of typically 2 Jcm-2 is required. With a system resolution in the plane of the array (i.e. perpendicular to substrate motion) of 200 dpi with a corresponding pitch of 127 um and a spot size of ˜120 um, the output power required to image on a substrate coated with the known colour change technology and moving at 2 m/s is approximately 5 W emitted by each optical fibre emission channel in the array.

There is though a desire to increase the target or imaging speed to at least 3 m/s and potentially to 5 m/s and beyond. However, to image at higher speeds it is necessary to either increase laser power applied to the substrate, increase the power density by using a smaller spot size or increase the sensitivity of the substrate. To induce a colour change reaction, a certain energy density is required and in addition there is a minimum power density required which defines the minimum time required to deposit the energy. As the speed of the substrate increases, the time allowed to image a dot or pixel becomes shorter and hence the laser power requirement increases. Increasing the sensitivity of the substrate generally has a negative impact on background colour stability and so is less desirable than increasing the power or power density to achieve faster imaging speeds.

With multi-emitter array ‘printers’ having a laser diode coupled with each emission channel, the reliability of the system is reduced compared to conventional system having only a single laser source by the fact that a large number of sources are used, since a failure of any of the laser diodes can leave a gap in the image produced. For laser diodes, reliability is strongly related to output power or power and current and operating temperature. For a single laser diode operating in the near infrared (NIR) region, the relationship between failure and relevant variables may be expressed mathematically as:

$$FR = {FR}_{o} . {I}^{x} . {P}^{y} . exp ( - \frac{E a}{k . {T}_{jn}} ) \qquad ( 1 )$$

Where FR is the failure rate (measured in FIT or kFIT where one FIT is one failure in 10⁹ device hours), I is the laser drive current, P the laser diode output power, x the acceleration factor for current, y the acceleration factor for laser power, Ea the activation energy, k Boltzmann's constant and Tⱼₙ the laser diode junction temperature and FRₒ is an arbitrary constant failure rate determined from experiments.

Acceleration values of x=0 and y=5 are typical and it is apparent then that the failure rate is strongly dependent on the laser power through the fifth power indices.

The expected lifetime of a system containing n_{D} laser diodes may be estimated using the mathematical equation:

$${t}_{e} = \frac{- 1 {0}^{9}}{FIT . {n}_{D}} ln ( R ( {t}_{D} ) ) \qquad ( 2 )$$

Where FIT is the Failure in Time value for individual laser diodes, n_{D} is the number of laser diodes and R(t_{D}) is the required reliability.

As an example, to achieve a reasonable lifetime of say 19,000 hrs (at 50% duty cycle) for a system containing 384 laser diodes with a reliability factor of 0.8 (i.e. 80% of the systems will still be operating after the elapsed time with one laser diode failure) the FR (or FIT) value needs to be in the region 0.029 kFIT. To achieve this value from a single laser diode, the device has to be operated at a maximum operating power level (Pₒₚ) which is significantly below its maximum rated power output (Pₘ). For example, a laser having a Pₘ of 8 W will have to be operated at a maximum Pₒₚ<=5 W, which is sufficient for imaging at speeds of up to 2 m/s in the known systems.

In order to achieve imaging at speeds of around 3.2 m/s, one approach would be to increase laser power by the factor 3.2/2=1.60. Thus the laser power applied to the substrate through each emission channel would have to be increased to from 5 W to 8 W to achieve imaging speeds of around 3.2 m/s. However, operating an 8 W Pₘ rated laser diode at or near its maximum rated power would reduce the system lifetime expectancy by a factor of 10. For the example described above, the 19,000 hrs is reduced to 1,900 hrs. This is too low for modern industrial equipment.

One possible solution to this problem is to use individual laser diodes with a higher Pₘ and operate these at maximum operating power level Pₒₚ required to achieve the desired imaging speeds of ˜3.2 m/s but which is sufficiently below the maximum rated power Pₘ to achieve acceptable failure rates. For example, a 12 W Pₘ rated device operating at 7.5 W Pₒₚ has the same derating as an 8 W Pₘ rated laser operating at a maximum operating power Pₒₚ of 5 W. However, reliability calculations have shown that for the same lifetime requirement, a 12 W Pₘ rated laser diode has to be operated at a lower Pₒₚ than expected when compared to the 8 W Pₘ rated device. A contributing factor in this is the higher diode junction temperature for the 12 W laser diode device. Calculations suggest a Pₒₚ/Pₘₐₓ ratio of 0.55 is required for the 12 W Pₘ laser compared to 0.588 for the 8 W Pₘ laser diode to achieve the same level of reliability. Accordingly, whilst this approach offers increased imaging speed for the same expected system lifetime, it is not sufficient to achieve imaging speeds of 3.2 m/s without reducing reliability. To achieve imaging speeds of 3.2 m/s or above requires a laser power output per emission channel of >=7.5 W. Whereas, the predicted maximum operating power output Pₒₚ for good reliability from a 12 W Pₘ diode is 6 W at a junction temp of 316K. This is only sufficient to achieve imaging speeds of around 2.75 m/s.

Rather than increasing the laser power to achieve increased imaging speeds, it is possible to increase the power density by reducing the spot size. For example, if the system resolution is increased from 200 dpi to 300 dpi so that the spot size is reduced to 80 um, an imaging speed of around 3.2 m/s may be achieved with a laser power of ˜5 W per emitter. However, the total number of laser sources has to be increased by a factor of 1.5 and so the expected system lifetime is reduced by this factor from 19,000 to below 13,000 hrs.

There is a need then for a system for laser marking a substrate which is capable of achieving faster operational speeds whilst maintaining acceptable levels of reliability.

There is a need in particular for an alternative system for laser marking a moving substrate comprising a multi-emitter array which is capable of achieving imaging speeds of 3 m/s or more whilst maintaining acceptable levels of reliability.

There is also a need for an alternative method of operating a system for laser marking a substrate comprising a multi-emitter array which is capable of achieving faster operational speeds whilst maintaining acceptable levels of reliability.

### SUMMARY OF THE INVENTION

According to a first aspect of the invention, there is provided a system for laser marking a substrate, the system comprising a multi-emitter array having a plurality of emission channels, the emitting ends of which are arranged in an array, wherein each emission channel is coupled with at least two laser diodes and the system is configured, in use, to operate each laser diode at a maximum operational output power (Pₒₚ) that is less than 50% of its rated maximum power (Pₘ).

By coupling more than one laser diode to each emission channel in the multi-emitter array and operating the laser diodes at a maximum operational output power (Pₒₚ) less than 50% of their rated maximum power (Pₘ), the system is able to provide a combined emission from each emission channel having a power sufficiently high to enable faster operating speeds whilst achieving acceptable levels of reliability. Although there is an increase in the overall number of laser diodes in the system compared to system having only a single laser diode coupled to each emission channel, the reliability gain from operating each laser diode at a maximum operational output power (Pop) less than 50% of their rated maximum power (Pₘ) more than offsets any drop in reliability due to the increase in the number of laser diodes, resulting in a net improvement in reliability at the faster operational speeds.

In an embodiment, the system is configured, in use, to operate each laser diode at a maximum operational output power (Pₒₚ) that is less than 63% of its rated maximum power (Pₘ).

The system may be configured such that, in use, the ratio of maximum operating output power Pₒₚ to maximum rated output power Pₘ of each laser diode satisfies the relationship:

$$\frac{{P}_{op}}{{P}_{m}} \leq {( \frac{1.58 * 1 {0}^{- 6}}{{n}_{c} . {n}_{p}} {e}^{5.22 x 1 {0}^{3} / {T}_{j n}} )}^{1 / 5}$$

where n_{c} is the number of emission channels, nₚ the number of laser diodes coupled to each emission channel and their product is >=32 and Tⱼₙ is the laser diode junction temperature in Kelvin.

The laser diodes coupled with each emission channel may emit radiation at substantially the same wavelength and, in an embodiment, all the laser diodes may emit radiation at substantially the same wavelength. The laser diodes may emit radiation at a wavelength in the range of 900 nm to 1500 nm or at a wavelength in the range of 395 nm to 470 nm.

In an embodiment, the multi-emitter array is a multi-fibre array, the multi-fibre array comprising an array of emitting ends of optical fibres, each optical fibre defining one of said emission channels and being coupled with said at least two laser diodes at the opposing end. In this embodiment, the optical fibres may have a numerical aperture equal to or less than 0.24 and more preferably a numerical aperture in the range of 0.10 and 0.17.

The system may be configured to maintain the case temperature of the laser diodes on or below 25° C. in use.

The system may comprise means for producing relative movement between a substrate to be marked and the multi-emitter array at speeds equal to or above 3 m/s. The system may comprise a conveyance mechanism for moving a substrate to be marked relative to the multi-emitter array at speeds equal to or above 3 m/s.

In an embodiment, the system is part of a substrate marking system for marking a substrate susceptible to colour change upon irradiation, the system having means for controlling emission of radiation from the laser diodes so as to controllably irradiate selected areas of the substrate with desired quantities of radiation so as to mark the substrate in a desired manner. The substrate may have a coating comprising a TAG leuco dye or AOM. A colour change region of the substrate may incorporate a NIR (near infrared) absorber which is effective in the radiation wavelength range 900 nm to 1500 nm. Alternatively the colour change region may respond to radiation with wavelengths in the range 395 nm to 470 nm.

In accordance with a second aspect of the invention, there is provided a system for marking a substrate susceptible to colour change upon irradiation, the system comprising a plurality of optical fibres, the emitter ends of the optical fibres being arranged in an array, with at least two laser diodes coupled with each optical fibre at the opposing end, the system configured such that, in use, each laser diode is operated at a maximum operational output power (Pₒₚ) that is less than 50% of its rated maximum power (Pₘ).

The system in accordance with the second aspect of the invention may include any of the features of the system according to the first aspect of the invention as set out above.

In accordance with a third aspect of the invention, there is provided a method of laser marking a substrate using a system comprising a multi-emitter array for directing radiation onto the substrate, wherein the multi-emitter array defines a plurality of emission channels, the emitting ends of which channels are arranged in an array, and each emission channel is coupled with at least two laser diodes, the method comprising operating each laser diode at a maximum operational output power (Pₒₚ) that is less than 50% of its rated maximum power (Pₘ).

Operating the laser diodes a maximum operational output power (Pₒₚ) that is less than 50% of their rated maximum power (Pₘ) enables acceptable levels of reliability of the system to be achieved whilst the power of the combined radiation emitted through each channel is sufficiently high as to enable faster operating speeds. Although there is an increase in the overall number of laser diodes in the system compared to system having only a single laser diode coupled to each emission channel, the reliability gain from operating each laser diode at a maximum operational output power (Pₒₚ) less than 50% of their rated maximum power (Pₘ) more than offsets any drop in reliability due to the increase in the number of laser diodes, resulting in a net improvement in reliability at the faster operational speeds.

In an embodiment, the method comprises operating each laser diode at a maximum operational output power (Pₒₚ) that is less than 63% of its rated maximum power (Pₘ).

In an embodiment, the method comprises operating the system such that the ratio of maximum operating output power Pₒₚ to maximum rated output power Pₘ of each laser diode satisfies the relationship:

$$\frac{{P}_{op}}{{P}_{m}} \leq {( \frac{1.58 * 1 {0}^{- 6}}{{n}_{c} . {n}_{p}} {e}^{5.22 x 1 {0}^{3} / {T}_{j n}} )}^{1 {/}_{5}}$$

where n_{c} is the number of emission channels, nₚ the number of laser diodes coupled to each emission channel and their product is >=32 and Tⱼₙ is the laser diode junction temperature in Kelvin.

The system may comprise a system in accordance with either of the first and second aspects of the invention.

The method may comprise maintaining the case temperature of the laser diodes at or below 25° C.

The method may comprise moving the substrate relative to multi-emitter array at speeds equal to or above 3 m/s whilst irradiating the substrate.

The substrate may be susceptible to colour change when irradiated and the method may comprise controlling the radiation emitted by the laser diodes such that the radiation emitted through each of the emission channels irradiates selected areas of the substrate with desired quantities of radiation so as to mark the substrate in a desired manner. The method may comprise marking the substrate whilst it moves at speeds of 3 m/s or more relative to the multi-emitter array. The substrate may have a coating comprising a TAG leuco dye or AOM. A colour change region of the substrate may incorporate a NIR (near infrared) absorber which is effective in the radiation wavelength range 900 nm to 1500 nm and the laser diodes may emit radiation at a wavelength falling within the range of the NIR absorber. Alternatively the colour change region may respond to radiation in the range 395 nm to 470 nm and the laser diodes may emit radiation at a wavelength falling within said range

In accordance with a fourth aspect of the invention, there is provided a method of marking a substrate susceptible to colour change when irradiated using a system comprising a plurality of optical fibres, emitter ends of the optical fibres being arranged in an array, and wherein at least two laser diodes are coupled with each optical fibre at the opposing end, the method comprising operating each laser diode at a maximum operational output power (Pₒₚ) that is less than 50% of its rated maximum power (Pₘ).

The method according to the fourth aspect of the invention may comprise any of the features of the method according to the third aspect of the invention set out above.

### DETAILED DESCRIPTION OF THE INVENTION

In order that the invention may be more clearly understood an embodiment thereof will now be described, by way of example only, with reference to the accompanying drawings, of which:

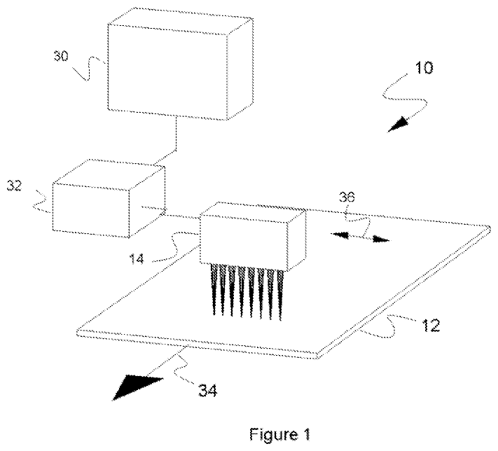

FIG. 1 illustrates schematically an embodiment of a system for laser marking a substrate in accordance with an aspect of the invention; and

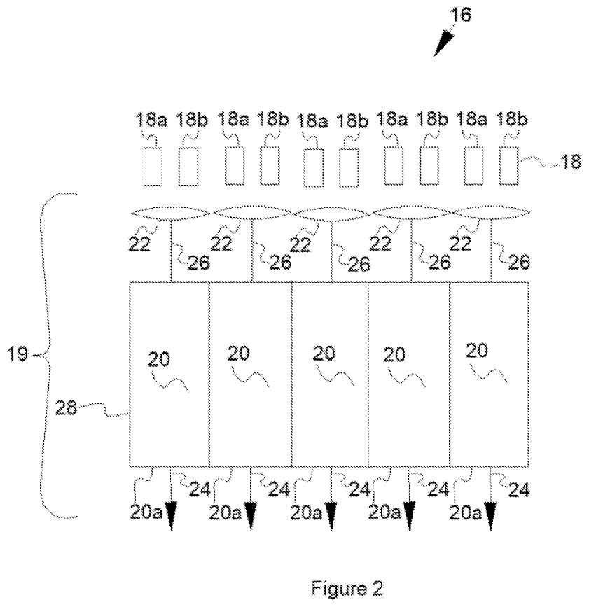

FIG. 2 is a schematic illustration of multi-emitter array forming part of an imaging head of the system of FIG. 1.

Turning now to FIG. 1, a system 10 for laser marking a substrate 12 is shown. The system 10 includes an imaging head 14 and is suitable for marking a substrate 12 which includes material susceptible to changing colour upon irradiation, so as to form an image.

The substrate 12 may be any suitable substrate which is susceptible to changing colour when irradiated. Such colour change technology is known in the art, for example from WO2016135468 A1, WO2016097667 A1, WO2015015200 A1, and WO2010026408 A2, to which the reader should refer for further details. The contents of WO2016135468 A1, WO2016097667 A1, WO2015015200 A1, and WO2010026408 A2 are hereby incorporated by reference. In accordance with one non-limiting embodiment, the substrate 12 is susceptible to colour change when irradiated by radiation in the NIR wavelength range 900 nm to 1500 nm and may comprise a NIR absorber. In an alternative non-limiting embodiment, the substrate is susceptible to colour change when irradiated by radiation having a wavelength in the range 395 nm to 470 nm

As illustrated schematically in FIG. 2, the imaging head 14 contains a multi-emitter array 16 comprising a number of laser diodes 18 and a radiation guide 19 for directing radiation from the laser diodes onto the substrate 12. The radiation guide 19 comprises a number of discrete emission channels 20, each of which has an emitter end 20a from which radiation from the laser diodes 18 is directed onto a selected area of the substrate in use. At least the emitter ends 20a of the emission channels 20 are arranged in an array. The laser diodes 18 are arranged in groups of two 18a, 18b, with each group of diodes being coupled with the opposing, inlet end of a respective one of the emission channels 20 by suitable coupling optics 22. The radiation emitted by all the diodes 18a, 18b in each group is combined and directed through the respective emission channel 20 to form a combined emission 24 which is directed onto the substrate 12 from the emitter end 20a. In the present embodiment, the multi-emitter array is a multi-fibre array having a number of optical fibres 26 which each define one of the emission channels 20. The emitting ends of the fibres 26 extend through a coupling block 28 which holds the emitting ends in an array. However, optical or radiation guide means other than optical fibres could be adopted provided they can be arranged to define discrete emission channels 20 in which the emitter ends 20a are arranged in array. In this regard, the term multi-emitter array should be understood as referring to an arrangement in which the emitting ends of multiple optical fibres or other optical or radiation guide means are arranged in an array. Whilst FIG. 2 illustrates the input ends of the optical fibres 26 (or other optical or radiation guide means) and the laser diodes 18 being aligned in an array, this is not essential and they can be configured in any suitable manner for incorporation in the imaging head 14 or indeed outside the head.

FIG. 2 is a schematic illustration which shows a simplified imaging head 14 with five discrete emission channels 20, in which the emitter ends 20a of the channels arranged in a one dimensional array and two laser diodes 18a, 18b are coupled to each channel. It should be understood though that the number of emission channels 20, the number of laser diodes 18, and the configuration of the emitter ends 20a can be varied as required to provide an array of the desired shape, size and resolution. For example, in a typical printing head there may be hundreds of emission channels 20 with a corresponding number of laser diodes and the emitter ends 20a of the emission channels 20 could be arranged in a two dimensional array or other configuration. It should also be understood that the number of laser diodes 18 coupled in a group with each emission channel/optical fibre 20 is not limited to two but can be three or more. Accordingly, the laser diodes 18 can be arranged in groups of three or more, with the laser diodes in each group being coupled with a respective emission channel/optical fibre 20.

The laser diodes 18 are selected and operated to emit radiation in a suitable wavelength to produce a colour change in the substrate. For example, for use with a substrate 12 susceptible to colour change when irradiated by radiation in the NIR wavelength, the laser diodes 18 emit radiation in the NIR wavelength, typically in the wavelength range 900 nm to 1500 nm. Alternatively, for use with other colour change substrates, the laser diodes could be selected and operated to emit radiation in the wavelength range 395 nm to 470 nm.

The laser diodes 18, or at least each group of laser diodes 18a, 18b, are individually addressable and are individually controlled by a microprocessor 30 via a drive amplifier 32.

The microprocessor 30 is operable to convert a digital image file to a set of emission instructions for the multi-emitter array 16. Typically, this involves mapping a particular pixel in the image file to a particular spot or area of the substrate 12; and determining the irradiation (duration and/or intensity) required from the individual emission channels 20 in the imaging head 14 to change the colour of each spot or area of the substrate to a colour matching that of each image pixel. Each of the optical fibre emission channels 20 directs the combined emission 24 of the respective diodes 18a, 18b coupled to it onto a spot on the surface of the substrate 12, such that a specific continuous (or discontinuous) pattern of irradiated spots is formed when the laser diodes are emitting. The system is arranged so that the combined emission 24 from the various emission channels 20 forms a pattern of irradiated spots on the substrate 12 which matches the pixels in an image file.

A further lens or other optical guidance arrangement may be provided between the emitter ends 20a of the optical fibres 26 or other emission channels 20 and the substrate.

The system has a conveyance mechanism (not shown) for moving the substrate 12 relative to the imaging head 14 and the microprocessor 30 is further operable to respond to the movement of substrate 12 relative to the imaging head 14. This movement may take place in a single direction as indicated by arrow 34 in FIG. 1 or in multiple directions. Typically, at faster operating speeds the substrate moves continuously in a single direction as indicated by the arrow 34.

The power of the combined emission 24 from each of the emission channels 20 is the sum of the output power from each of the laser diodes 18a, 18b coupled with it, subject to any losses in the optical system between the laser diodes and the substrate, including in this embodiment the coupling optics 22 and optical fibre 26. As discussed previously, imaging speed is dependent on the power of the radiation directed onto the substrate through each emission channel, with a power of >=7.5 W required to achieve imaging speeds of 3.2 m/s and above at a resolution of 200 dpi. By coupling two or more laser diodes 18a, 18b to each fibre optical channel 20, it is possible to obtain a combined emission 24 from each channel which has a high enough power to enable increased imaging speeds, say in excess of 3 m/s, to be achieved whilst operating each laser diode 18 at a maximum operating power Pₒₚ which is sufficiently below its maximum rated power Pₘ that the reliability of the system is acceptable for modern manufacturing processes. For example, if two laser diodes each with a maximum power rating Pₘ of 8 W are coupled with each fibre optical emission channel 20, a combined emission power in the region of 8 W can be achieved whilst operating each diode at a maximum operating power Pₒₚ which is around 50% of its maximum rated power Pₘ. Using two laser diodes each with a Pₘ of 12 W would enable a combined emission of >=8 W to be achieved whilst operating the each diode with a maximum operating power Pₒₚ which is below 50% of its Pₘ. By coupling two, three or more laser diodes to each emission channel, a combined emission 24 from each channel having a power sufficient for high imaging speeds (e.g. above 3 m/s) can be achieved whilst maintaining a Pₒₚ/Pₘₐₓ ratio suitable for acceptable reliability using currently available laser diodes. It has been found that operating each laser diode 18 at a Pₒₚ which is below 50%, or below 63%, of its Pₘ achieves satisfactory reliability levels for the system. In particular, it has been found that acceptable levels of reliability can be achieved by configuring the system so that the ratio of maximum operating power Pₒₚ to maximum rated output power Pₘ for each diode satisfies the relationship

$$\frac{{P}_{op}}{{P}_{m}} \leq {( \frac{1.58 * 1 {0}^{- 6}}{{n}_{c} . {n}_{p}} {e}^{5.22 x 1 {0}^{3} / {T}_{j n}} )}^{1 {/}_{5}} \qquad ( 3 )$$

where n_{c} is the number of emission channels, nₚ the number of laser diodes coupled to each emission channel and their product is >=32, and Tⱼₙ is the laser diode junction temperature in Kelvin.

In an embodiment, the substrate 12 is susceptible to colour change when irradiated by radiation in the NIR wavelength range 900 nm to 1500 nm and may also contain a MR absorber to facilitate the use of NIR laser diodes. In particular, the colour change technology may comprise a metal oxyanion, a leuco dye, a diacetylene, and a charge transfer agent. The metal oxyanion may be a molybdate, which may be ammonium octamolybdate AOM. The colour change technology may further comprise an acid generating agent and leuco dye colour formers where the acid generators may be thermal acid generators (TAG) or photo-acid generators (PAG). The acid generating agent may be an amine salt of an organoboron or an organosilicon complex. In particular, the amine salt of an organoboron or an organosilicon complex may be tributylammonium borodisalicylate. The leuco dye colour former may be odb1 and odb2 and other colours. Suitable NIR absorbers include Indium Tin Oxide (ITO) and particularly non-stoichiometric reduced ITO, Copper Hydroxy Phosphate, Tungsten Oxides, doped Tungsten oxides and non-stochiometric doped tungsten oxides and organic NIR absorbing molecules such as copper pthalocyanines.

The above embodiment is described by way of example only. Many variations are possible without departing from the scope of the invention as defined in the appended claims. For example, whilst in the embodiment described the system is adapted for inkless printing of a substrate susceptible to colour change when irradiated, the system can be adapted for inkless printing of substrates which exhibit other visible changes in its physical properties when irradiated or indeed for other applications where a substrate is to be irradiated and where the speed of operation of the system is dependent on the power of radiation applied to the substrate.

1. A system for laser marking a substrate, the system comprising a multi-emitter array having a plurality of individually controllable discrete emission channels, each emission channel having an emitting end from which radiation is directed onto a selected area of the substrate in use, the emitting ends being arranged in an array, wherein each emission channel is coupled with at least two laser diodes and the system is configured, in use, to operate each laser diode at a maximum operating output power (Pₒₚ) that is less than 63% of its rated maximum power (Pₘ).

2. A system as claimed in claim 1, wherein the system is configured, in use, to operate each laser diode at a maximum operating output power (Pₒₚ) that is less than 50% of its rated maximum power (Pₘ).

3. A system as claimed in claim 1, wherein the system is such that, in use, the ratio of maximum operating output power Pₒₚ to maximum rated output power Pₘ of each laser diode satisfies the relationship:
$$\frac{{P}_{op}}{{P}_{m}} \leq {( \frac{1.58 * 1 {0}^{- 6}}{{n}_{c} . {n}_{p}} {e}^{5.22 x 1 {0}^{3} / {T}_{j n}} )}^{1 {/}_{5}}$$
where n_{c} is the number of emission channels, nₚ the number of laser diodes coupled to each emission channel and their product is >=32 and Tⱼₙ is the laser diode junction temperature in Kelvin.

4. A system as claimed in claim 1, wherein the laser diodes coupled with each emission channel emit radiation at substantially the same wavelength.

5. A system as claimed in claim 4, wherein all the laser diodes emit radiation at substantially the same wavelength.

6. A system as claimed in claim 1, wherein the laser diodes emit radiation at a wavelength in the range of 900 nm to 1500 nm or at a wavelength in the range of 395 nm to 470 nm.

7. A system as claimed in claim 1, wherein the multi-emitter array is a multi-fibre array, the multi-fibre array comprising an array of emitting ends of optical fibres, each optical fibre defining one of said emission channels and being coupled with said at least two laser diodes at the opposing end.

8. A system as claimed in claim 7, wherein the optical fibres have a numerical aperture equal to or less than 0.24 and more preferably a numerical aperture in the range of 0.10 and 0.17.

9. (canceled)

10. (canceled)

11. (canceled)

12. A system as claimed in claim 1, wherein the system is configured for use with a substrate having a coating comprising a TAG leuco dye or AOM.

13. A system for marking a substrate susceptible to colour change upon irradiation, the system comprising a plurality of optical fibres, each optical fibre having an emitter end from which radiation is directed onto the substrate in use, the emitter ends of the optical fibres being arranged in an array, and at least two laser diodes coupled with each optical fibre at the opposing end, the system configured such that, in use, each laser diode is operated at a maximum operating output power (Pₒₚ) that is less than 63% of its rated maximum power (Pₘ).

14. A method of laser marking a substrate using a system comprising a multi-emitter array for directing radiation onto the substrate, wherein the multi-emitter array defines a plurality of emission channels, the emitting ends of which are arranged in an array with each emitter end being configured to independently direct radiation onto the substrate in use, and wherein each emission channel is coupled with at least two laser diodes, the method comprising operating each laser diode at a maximum operating output power (Pₒₚ) that is less than 63% of its rated maximum power (Pₘ).

15. A method as claimed in claim 14, the method comprising operating each laser diode at a maximum operating output power (Pₒₚ) that is less than 50% of its rated maximum power (Pₘ).

16. A method as claimed in claim 14, the method comprising operating the system such that the ratio of maximum operating output power Pₒₚ to maximum rated output power Pₘ of each laser diode satisfies the relationship:
$$\frac{{P}_{op}}{{P}_{m}} \leq {( \frac{1.58 * 1 {0}^{- 6}}{{n}_{c} . {n}_{p}} {e}^{5.22 x 1 {0}^{3} / {T}_{j n}} )}^{1 {/}_{5}}$$
where n_{c} is the number of emission channels, nₚ the number of laser diodes coupled to each emission channel and their product is >=32, and Tⱼₙ is the laser diode junction temperature in Kelvin.

17. (canceled)

18. (canceled)

19. (canceled)

20. A method as claimed in claim 19, wherein the substrate has a coating comprising a TAG leuco dye or AOM.

21. A method as claimed in claim 19, wherein a colour change region of the substrate incorporates a NIR (near infrared) absorber which is effective in the radiation wavelength range 900 nm to 1500 nm and the laser diodes emit radiation at a wavelength falling within the range of the NIR absorber.

22. A method as claimed in claim 19, wherein a colour change region of the substrate responds to radiation in the range 395 nm to 470 nm and the laser diodes emit radiation at a wavelength falling within said range.

23. A method of marking a substrate susceptible to colour change when irradiated using a system comprising a plurality of optical fibres, emitter ends of the optical fibres being arranged in an array and each emitter end configured for independently directing radiation onto the substrate in use, and wherein at least two laser diodes are coupled with each optical fibre at the opposing end, the method comprising operating each laser diode at a maximum operating output power (Pₒₚ) that is less than 50% of its rated maximum power (Pₘ).

24. (canceled)

25. A system as claimed in claim 1, wherein the system has means for controlling emission of radiation from the laser diodes so as to controllably irradiate selected areas of the substrate with desired quantities of radiation so as to mark the substrate in a desired manner.

26. A method as claimed in any one of claim 14, wherein the substrate is susceptible to colour change when irradiated and the method comprises controlling the radiation emitted by the laser diodes such that the radiation emitted through each of the emission channels irradiates selected areas of the substrate with desired quantities of radiation so as to mark the substrate in a desired manner.
